(19) United States
(12) Patent Application Publication
(10) Pub. No.: US 2021/0365651 A1
(43) Pub. Date: Nov. 25, 2021

(54) IDENTIFICATION METHOD OF AN INTEGRATED CIRCUIT CHIP AND IDENTFICATION SYSTEM OF AN INTEGRATED CIRCUIT CHIP

(71) Applicant: POWERTECH TECHNOLOGY INC., Hsinchou County (TW)

(72) Inventors: Chi-Chung Yu, Hsinchou County (TW); Kai-Hung LIN, Hsinchou County (TW); Tien-Hung LOU, Hsinchou County (TW)

(21) Appl. No.: 17/037,949

(22) Filed: Sep. 30, 2020

(30) Foreign Application Priority Data
May 25, 2020 (TW) 109117396

(51) Int. Cl. G06K 7/14; G06K 19/06

(52) U.S. Cl. CPC G06K 7/1417; G06K 7/1413; G06K 19/06037; G06K 19/06028

(57) ABSTRACT

An identification method of an integrated circuit chip of the present invention includes identifying a surface structure or an internal structure of an integrated circuit chip, generating a structural information set according to the surface structure or internal structure, converting the structural information set into an identification information set. The identification information set generated by the above-mentioned identification method can be stored in a digital file, and a chip manufacturer requires no visible information printed on an outer surface of the integrated circuit chip such that factory information of the integrated circuit chip can be concealed. When retrieving the malfunctioned or defective integrated circuit chip, the manufacturer can acquire a new generated identification information set by identify the integrated circuit chip and compare the new generated identification information set and the generated identification information set stored in the file to obtain the factory information of the retrieved integrated circuit chip.

### FIELD OF INVENTION

The present invention relates to an identification method of an integrated circuit (IC) chip, especially to an identification method of an integrated circuit chip and an identification system of an integrated circuit chip, which directly scan a surface structure of a package casing and an internal structure of an integrated circuit chip and form an identification code of the integrated circuit chip based on the surface or internal structure.

### BACKGROUND OF INVENTION

In conventional chip manufacturing fields, an integrated circuit (IC) chip manufacturer, after finish the encapsulation of IC chips, a package casing of the IC chip is generally printed with a factory information set such as a model number, factory information details, a serial number, and a product manufacturer by a laser printing process or other printing process to later purposes of identification. The various information set are usually printed on package casings of the IC chips in form of general codes or two-dimensional barcodes.

Furthermore, an IC chip manufacturer usually provides and sells IC chips with the same specification to various downstream companies so the downstream company can produce electronic devices using the provided IC chips. Some downstream companies, based on reasons of confidentiality, promotion of private brand visibility of the electronic devices, and improvement of product consistency, require the IC chip manufacturer to physically wear off and remove the originally printed factory information sets of the package casings of the provided IC chips, and to print the name of the downstream company on the IC chip such that competitors have no inform about its upstream IC chip supplier in one aspect and unify exteriors of the IC chips supplied by different IC chip manufacturers in another aspect, to prevent customers of the electronic devices from changing their consumption propensity due to difference between the original manufacturers of the IC chips. Alternatively, the IC chip manufacturer can also have no information on the printed on the surfaces of the package casings of the IC chips in advance according to demands of the downstream companies to assist the downstream companies to hide related information.

However, removal of the original information on the surface of the package casing of the IC chip or lack of printed information on the package casing of the IC chip results in an issue of difficulty for the manufacturer inversely tracking the malfunctional or defective IC chip to its IC chip production line when maintenance or replacement is needed for the IC chip due to problems of malfunction or defects, which also disadvantages troubleshooting and defect removal.

Therefore, at current stage it is urgently needed for a method for recording a factory information of an IC chip record on the premise of no related information recorded on an exterior of the IC chip.

### SUMMARY OF INVENTION

The present invention, according to an issue that a factory information of a package casing surface of the conventional integrated circuit (IC) chip is removed or no factory information is printed on the IC chip in the factory so tracking the IC chip becomes difficult, mitigates and obviates shortcomings related to the issue and further invents an identification method of an integrated circuit chip.

A main objective of the present invention is to provide an identification method of an integrated circuit chip, comprising:

an identification step comprising identifying a surface structure or an internal structure of the integrated circuit chip, and generating a structural information set according to the surface structure or the internal structure; and

an identification information generation step comprising converting the structural information set to an identification information set of the integrated circuit chip.

In an embodiment of the present invention, the identification method of an integrated circuit chip further comprises an identification information output step comprising outputting the identification information set into a digital file, or simultaneously outputting the structural information set and the identification information set into digital files.

In an embodiment of the present invention, the surface structure is a surface bump texture structure, and the structural information set is a three-dimensional information set corresponding to the surface bump texture structure.

In an embodiment of the present invention, the internal structure is an internal bump texture structure in a depth range under a surface of the integrated circuit chip, and the structural information set is a three-dimensional information set corresponding to the internal bump texture structure.

In an embodiment of the present invention, the three-dimensional information set comprises a plurality of point coordinates, each of the point coordinates comprises a first horizontal coordinate, a second horizontal coordinate, and a vertical coordinate that are perpendicular to each other.

In an embodiment of the present invention, the identification information set comprises least one of a character code, a one-dimensional barcode, and a two-dimensional barcode.

In an embodiment of the present invention, the identification step comprises identifying the surface structure of the integrated circuit chip by an identification device, and generating the structural information set by the surface structure, wherein the identification device is an optical identification device.

In an embodiment of the present invention, the optical identification device is one of a visible light identification device comprising a visible light sensor, a laser identification device comprising a laser sensor, and an X-ray identification device comprising X-ray sensor.

In an embodiment of the present invention, the identification step comprises identifying a surface structure or an internal structure of the integrated circuit chip by an identification device, and generating the structural information set according to the surface structure or the internal structure, wherein the identification device is an ultrasonic identification device.

Another objective of the present invention is to provide an identification system of an integrated circuit chip, comprising:

an identification module, configured to identify a surface structure or an internal structure of the integrated circuit chip, and to generate a structural information set according to the surface structure or the internal structure; and

an identification information generation module, connected to the identification module, and configured to convert the structural information set from an identification information set of the integrated circuit chip.

In an embodiment of the present invention, the identification system of an integrated circuit chip further comprises an identification information output module connected to the identification information generation module, and configured to output the identification information set into a digital file, or to simultaneously output the structural information set and the identification information set into digital files respectively.

According to the above technical solution, the identification method of an integrated circuit chip and the identification system of an integrated circuit chip of the present invention have advantages as follows:

1. The identification method of an integrated circuit chip and the identification system of an integrated circuit chip of the present invention can identify a surface structure or an internal structure of an integrated circuit chip and generate a structural information set according to the surface structure or the internal structure, then convert the structural information set into an identification information set of the integrated circuit chip to achieve a purpose of establishment of an identification information set according to a surface bump texture structure or an internal bump texture structure of each integrated circuit chip without printing factory information on the surface of the integrated circuit chip. Because an identification information set (a character code including characters and numerals, one-dimensional barcode, or two-dimensional barcode) can be established through the above method and system without printing on the surface of the integrated circuit chip, an effect of concealment of the factory information of the integrated circuit chip has been reached.

2. The above identification information set can be linked to factory information to be established previously by a manufacturer for the integrated circuit chip, including model number, factory information, serial number, product manufacturer, etc. Because the surface bump texture structure or the internal bump texture structure of each of the integrated circuit chip is an unique structure, therefore the structural information set and the identification information set established therefor is also unique and would not get into a situation that different integrated circuit chips are mistakenly recorded as the same one.

3. Because an integrated circuit chip manufacturer identifies each integrated circuit chip and establish a corresponding identification information set through the identification method of an integrated circuit chip and the identification system of an integrated circuit chip of the present invention before the integrated circuit chip is out of the factory, the present invention can achieve identity management for each integrated circuit chip. When an integrated circuit chip has a malfunction or defect issue during later sale and use and returns to its manufacturer, the manufacturer can use the above-mentioned identification method of an integrated circuit chip and the identification system of an integrated circuit chip to scan the integrated circuit chip to acquire a corresponding identification information set and checks the corresponding identification information set with a previously established factory information set to further acquire a production line and a manufacture batch to which the integrated circuit chip belongs, which advantages continuous improvement for the integrated circuit chip itself and its manufacturing process.

### DESCRIPTION OF DRAWINGS

FIG. 1 is a schematic flowchart of steps of the present invention identification method of an integrated circuit chip.

FIG. 2 is a schematic framework diagram of the present invention identification system of an integrated circuit chip.

FIG. 3 is a schematic operational perspective view of the integrated circuit chip method and system of the present invention identifying an integrated circuit chip.

FIG. 4 is a schematic operational partial-section side view of the integrated circuit chip method and system of the present invention identifying a surface structure of an integrated circuit chip through an optical identification device.

FIG. 5 is a schematic operational partial-section side view of the integrated circuit chip method and system of the present invention identifying a surface structure of an integrated circuit chip through an ultrasonic identification device.

FIG. 6 is a schematic operational partial-section side view of the integrated circuit chip method and system of the present invention identifying an internal structure of an integrated circuit chip through an ultrasonic identification device.

### DETAILED DESCRIPTION OF PREFERRED EMBODIMENTS

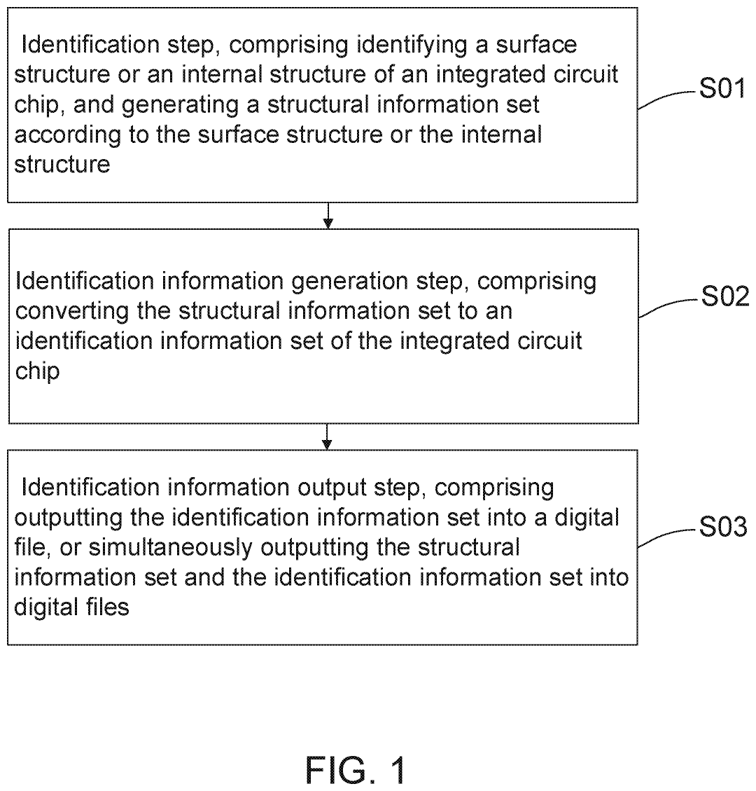

With reference to FIG. 1, the present invention provides an identification method of an integrated circuit chip (IC), the identification method of an integrated circuit chip comprises: an identification step S01, an identification information generation step S02, and an identification information output step S03.

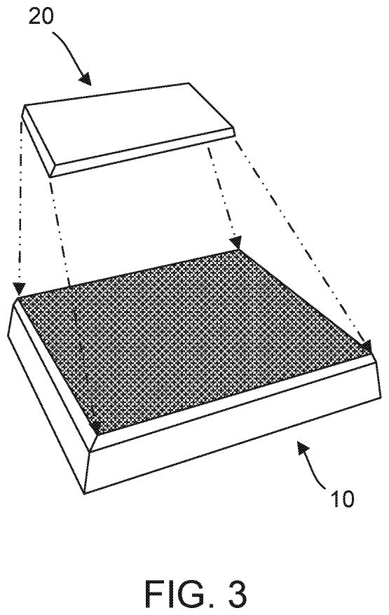

With reference to FIGS. 3 to 6, the identification step S01 comprises identifying a surface structure 111 or an internal structure 121 of the integrated circuit chip 10, and generating a structural information set according to the surface structure 111 or the internal structure 121. The integrated circuit chip 10 generally comprises a package casing 11 made of epoxy molding compound and a semiconductor die 12 encapsulated by the package casing 11. The surface structure 111 refers to a surface structure 111 of the package casing 11. The internal structure 121 refers to an internal structure at a certain depth or a certain narrow depth range in the package casing 11, or refers to an internal structure 121 in a certain depth or a certain narrow depth range in the semiconductor die 12.

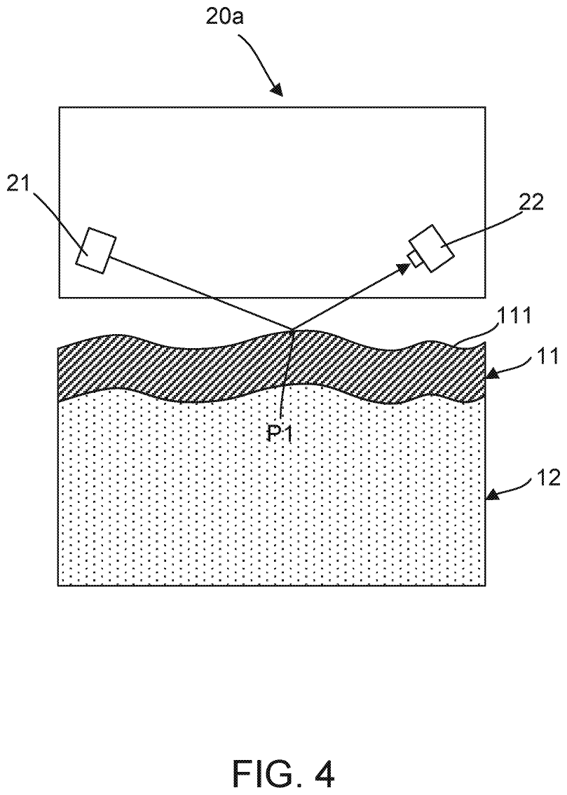

With reference to FIG. 4, in an embodiment of the present invention, the identification step S01 comprises identifying the surface structure 111 of the integrated circuit chip 10 through an identification device 20, and generating the structural information set according to the surface structure 111, and the identification device 20 is an optical identification device 20a. Specifically, the optical identification device 20a is one of a visible light identification device comprising a visible light sensor, a laser identification device comprising a laser sensor, and an X-ray identification device comprising an X-ray sensor. Furthermore, the optical identification device 20a comprises at least one optical transmitter 21 and at least one optical receiver 22. The optical transmitter 21 emits light to the surface structure 111 of the integrated circuit chip 10 and the light is reflected back to the optical receiver 22, and allows optical information in a reflected area to be the structural information set.

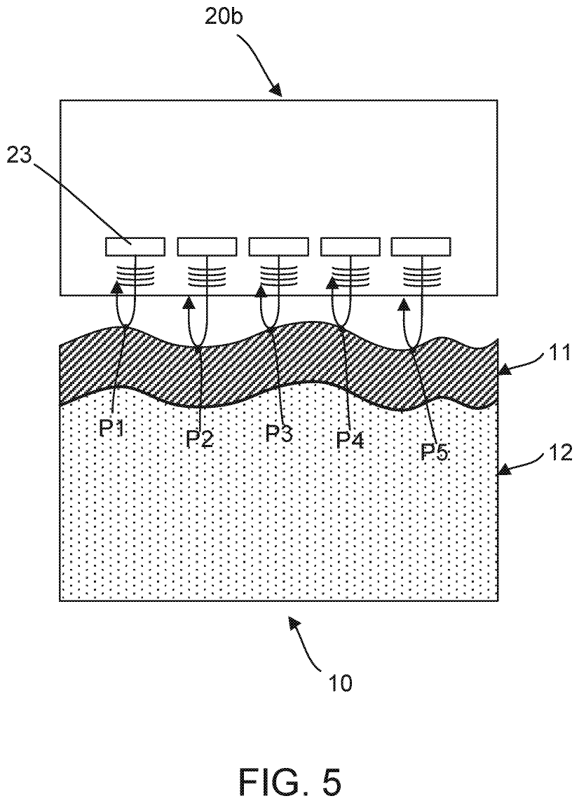

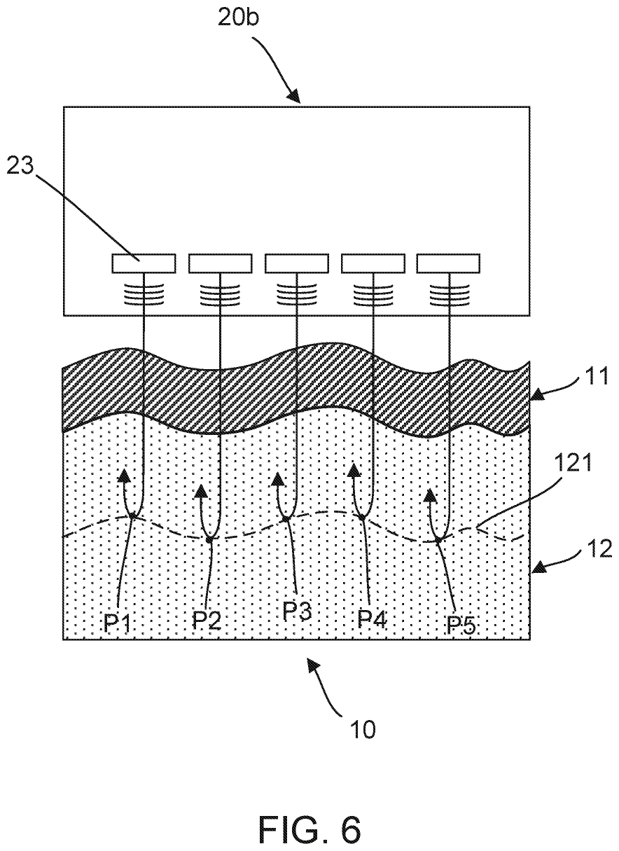

With reference to FIGS. 5 and 6, in another embodiment of the present invention, the identification step S01 comprises identifying a surface structure 111 or an internal structure 121 of the integrated circuit chip 10 through an identification device 20, and generating the structural information set according to the surface structure 111 or the internal structure 121, and the identification device 20 is an ultrasonic identification device 20b. The characteristic of the ultrasonic identification device 20b is that an ultrasonic wave irradiated from the ultrasonic identification device 20b can penetrate a solid medium or a liquid medium to reach a specific depth in the medium. Therefore, the ultrasonic identification device 20b can emit an ultrasonic wave to detect the surface structure 111 of the integrated circuit chip 10 without penetrating the integrated circuit chip 10, or emit an ultrasonic wave penetrating the integrated circuit chip 10 to detect internal structure 121. Furthermore, the ultrasonic identification device 20b comprises a plurality of ultrasonic transceivers 23 each of which is able to emit an ultrasonic wave to the surface structure 111 of the integrated circuit chip 10 or the internal structure 121 of a specific depth, and receive a reflected ultrasonic wave to detect and acquire ultrasonic information of the surface or internal structure as the structural information set.

In an embodiment of the present invention, the surface structure 111 is a surface bump texture structure, the structural information set corresponds to the three-dimensional information set of the surface bump texture structure, and the surface bump texture structure comprises ridge structures and valley structures. Specifically, the three-dimensional information set comprises a plurality of point coordinates P1, P2, P3, P4, P5, as shown in FIGS. 4 to 6. Each of the point coordinates P1, P2, P3, P4, P5 comprises a first horizontal coordinate, a second horizontal coordinate, and a vertical coordinate that are perpendicular to each other. For example, the three coordinates are an X-axis coordinate, a Y-axis coordinate, and a Z-axis coordinate.

In another embodiment of the present invention, the internal structure 121 is an internal bump texture structure at a certain depth or in a certain narrow depth range under the surface of the integrated circuit chip, the structural information set is a three-dimensional information set corresponding to the internal bump texture structure. Specifically, the three-dimensional information set comprises a plurality of point coordinates P1, P2, P3, P4, P5, as shown in FIGS. 4 to 6. Each of the point coordinates P1, P2, P3, P4, P5 comprises a first horizontal coordinate, a second horizontal coordinate, and a vertical coordinate that are perpendicular to one another. For example, the three coordinates are an X-axis coordinate, a Y-axis coordinate, and a Z-axis coordinate.

The identification information generation step S02 comprises converting the structural information set into an identification information set of the integrated circuit chip 10. In an embodiment of the present invention, the identification information set comprises at least one of a character code, a one-dimensional barcode, and a two-dimensional barcode. the character code can comprise characters and numerals in various languages, and usually English characters and Arabic numerals constitute the character code, for example, the character code is XYZ98765.

The identification information output step S03 comprises outputting the identification information set into a digital file, or simultaneously outputting the structural information set and the identification information set into a digital file or multiple digital files. The digital file can be any format capable of recording the digital information, and includes a TXT format, a CLS format, a DOC format, a DOCX format, a PPT format, a PPTX format, a PDF format, or any other known format. Furthermore, in a situation of the present invention identification method of an integrated circuit chip implemented repeatedly for a plurality of integrated circuit chips 10, the identification information sets outputted by the implemented identification information output steps S03 can be exported to a single digital file such that the single digital file comprises multiple identification information sets, which advantages integration and management of the identification information sets of the integrated circuit chips 10 of the same manufacture batch or the same sale batch.

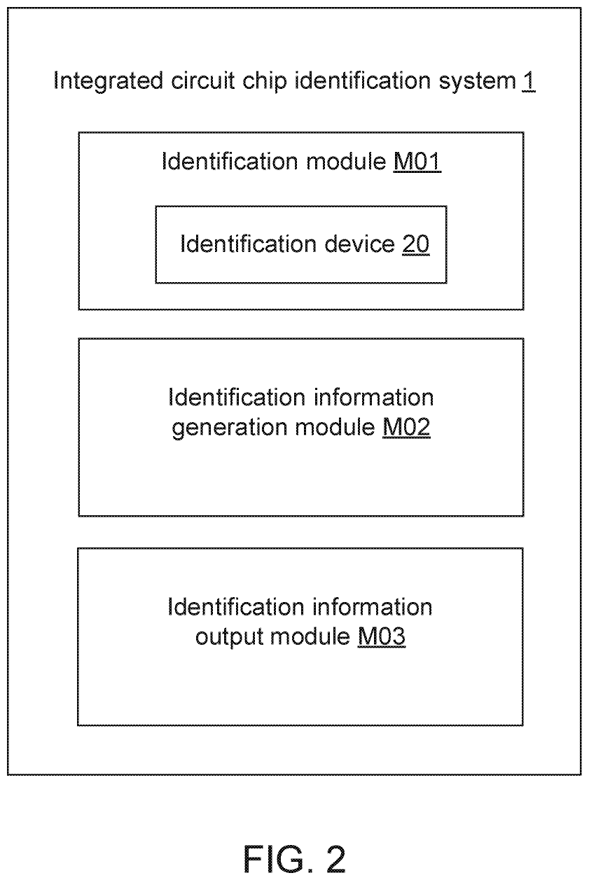

With reference to FIG. 2, the present invention also provides an identification system of an integrated circuit chip 1, comprising: an identification module M01, an identification information generation module M02, and an identification information output module M03.

With reference to FIGS. 3 to 6, the identification module M01 is configured to identify a surface structure 111 or an internal structure 121 of the integrated circuit chip 10, and generate a structural information set according to the surface structure 111 or the internal structure 121. The integrated circuit chip 10 generally comprises a package casing 11 made of epoxy molding compound and a semiconductor die 12 encapsulated by the package casing 11. The surface structure 111 refers to a surface structure 111 of the package casing 11. The internal structure 121 refers to an internal structure at a certain depth or a certain narrow depth range in the package casing 11, or refers to an internal structure 121 in a certain depth or a certain narrow depth range in the semiconductor die 12.

With reference to FIG. 4, in an embodiment of the present invention, the identification module M01 is configured to identify a surface structure 111 of the integrated circuit chip 10 through an identification device 20, and generate the structural information set according to the surface structure 111. The identification device 20 is an optical identification device 20a. Specifically, the optical identification device 20a is one of a visible light identification device comprising a visible light sensor, a laser identification device comprising a laser sensor, and an X-ray identification device comprising an X-ray sensor. Furthermore, the optical identification device 20a comprises at least one optical transmitter 21 and at least one optical receiver 22. The optical transmitter 21 emits light to the surface structure 111 of the integrated circuit chip 10 and the light is reflected back to the optical receiver 22, and allows optical information in a reflected area to be the structural information set.

With reference to FIGS. 5 and 6, in another embodiment of the present invention, the identification module M01 is configured to through an identification device 20 identify a surface structure 111 or an internal structure 121 of the integrated circuit chip 10, and generate a structural information set according to the surface structure 111 or the internal structure 121 and, and the identification device 20 is an ultrasonic identification device 20b. The characteristic of the ultrasonic identification device 20b is that an ultrasonic wave irradiated from the ultrasonic identification device 20b can penetrate a solid medium or a liquid medium to reach a specific depth in the medium. Therefore, the ultrasonic identification device 20b can emit an ultrasonic wave to detect the surface structure 111 of the integrated circuit chip 10 without penetrating the integrated circuit chip 10, or emit an ultrasonic wave penetrating the integrated circuit chip 10 to detect internal structure 121. Furthermore, the ultrasonic identification device 20b comprises a plurality of ultrasonic transceivers 23 each of which is able to emit an ultrasonic wave to the surface structure 111 of the integrated circuit chip 10 or the internal structure 121 of a specific depth, and receive a reflected ultrasonic wave to detect and acquire ultrasonic information of the surface or internal structure as the structural information set.

The identification information generation module M02 is connected to the identification module M01, and is configured to convert the structural information set into an identification information set of the integrated circuit chip 10. In an embodiment of the present invention, the identification information set comprises at least one of a character code, a one-dimensional barcode, and a two-dimensional barcode. the character code can comprise characters and numerals in various languages, and usually English characters and Arabic numerals constitute the character code, for example, the character code is XYZ98765.

The identification information output module M03 is connected to the identification information generation module M02, and is configured to output the identification information set into a digital file, or simultaneously output the structural information set and the identification information set into a digital file or multiple digital files. The digital file can be any format capable of recording the digital information, and includes a TXT format, a CLS format, a DOC format, a DOCX format, a PPT format, a PPTX format, a PDF format, or any other known format.

In an embodiment of the present invention, the surface structure 111 is a surface bump texture structure, the structural information set corresponds to the three-dimensional information set of the surface bump texture structure, and the surface bump texture structure comprises ridge structures and valley structures. Specifically, the three-dimensional information set comprises a plurality of point coordinates P1, P2, P3, P4, P5, as shown in FIGS. 4 to 6. Each of the point coordinates P1, P2, P3, P4, P5 comprises a first horizontal coordinate, a second horizontal coordinate, and a vertical coordinate that are perpendicular to each other. For example, the three coordinates are an X-axis coordinate, a Y-axis coordinate, and a Z-axis coordinate.

In another embodiment of the present invention, the internal structure 121 is an internal bump texture structure at a certain depth or in a certain narrow depth range under the surface of the integrated circuit chip, the structural information set is a three-dimensional information set corresponding to the internal bump texture structure. Specifically, the three-dimensional information set comprises a plurality of point coordinates P1, P2, P3, P4, P5, as shown in FIGS. 4 to 6. Each of the point coordinates P1, P2, P3, P4, P5 comprises a first horizontal coordinate, a second horizontal coordinate, and a vertical coordinate that are perpendicular to one another. For example, the three coordinates are an X-axis coordinate, a Y-axis coordinate, and a Z-axis coordinate.

According to the above technical solution, the identification method of an integrated circuit chip and the identification system of an integrated circuit chip 1 of the present invention have advantages as follows:

1. The integrated circuit chip 10 identification method and the identification system of an integrated circuit chip 1 of the present invention can identify a surface structure 111 or an internal structure 121 of an integrated circuit chip 10 and generate a structural information set according to the surface structure 111 or the internal structure 121, then convert the structural information set into an identification information set of the integrated circuit chip 10 to achieve a purpose of establishment of an identification information set according to a surface bump texture structure or an internal bump texture structure of each integrated circuit chip 10 without printing factory information on the surface of the integrated circuit chip 10. Because an identification information set (a character code including characters and numerals, one-dimensional barcode, or two-dimensional barcode) can be established through the above method and system without printing on the surface of the integrated circuit chip 10, an effect of concealment of the factory information of the integrated circuit chip 10 has been reached.

2. The above identification information set can be linked to factory information to be established previously by a manufacturer for the integrated circuit chip 10, including model number, factory information, serial number, product manufacturer, etc. Because the surface bump texture structure or the internal bump texture structure of each of the integrated circuit chip 10 is an unique structure, therefore the structural information set and the identification information set established therefor is also unique and would not get into a situation that different integrated circuit chip 10s are mistakenly recorded as the same one.

3. Because an integrated circuit chip 10 manufacturer identifies each integrated circuit chip 10 and establish a corresponding identification information set through the integrated circuit chip 10 identification method and the identification system of an integrated circuit chip 1 of the present invention before the integrated circuit chip 10 is out of the factory, the present invention can achieve identity management for each integrated circuit chip 10. When an integrated circuit chip 10 has a malfunction or defect issue during later sale and use and returns to its manufacturer, the manufacturer can use the above mentioned integrated circuit chip 10 identification method and the identification system of an integrated circuit chip 1 to scan the integrated circuit chip 10 to acquire a corresponding identification information set and checks the corresponding identification information set with a previously established factory information set to further acquire a production line and a manufacture batch to which the integrated circuit chip 10 belongs, which advantages continuous improvement for the integrated circuit chip 10 itself and its manufacturing process.

What is claimed is:

1. An identification method of an integrated circuit chip, comprising:
an identification step comprising identifying a surface structure or an internal structure of the integrated circuit chip, and generating a structural information set according to the surface structure or the internal structure; and
an identification information generation step comprising converting the structural information set to an identification information set of the integrated circuit chip.

2. The identification method of an integrated circuit chip as claimed in claim 1, further comprising an identification information output step comprising outputting the identification information set into a digital file, or simultaneously outputting the structural information set and the identification information set into digital files.

3. The identification method of an integrated circuit chip as claimed in claim 1, wherein the surface structure is a surface bump texture structure, and the structural information set is a three-dimensional information set corresponding to the surface bump texture structure.

4. The identification method of an integrated circuit chip as claimed in claim 1, wherein the internal structure is an internal bump texture structure in a depth range under a surface of the integrated circuit chip, and the structural information set is a three-dimensional information set corresponding to the internal bump texture structure.

5. The identification method of an integrated circuit chip as claimed in claim 3, wherein the three-dimensional information set comprises a plurality of point coordinates, each of the point coordinates comprises a first horizontal coordinate, a second horizontal coordinate, and a vertical coordinate that are perpendicular to each other.

6. The identification method of an integrated circuit chip as claimed in claim 4, wherein the three-dimensional information set comprises a plurality of point coordinates, each of the point coordinates comprises a first horizontal coordinate, a second horizontal coordinate, and a vertical coordinate that are perpendicular to each other.

7. The identification method of an integrated circuit chip as claimed in claim 1, wherein the identification information set comprises least one of a character code, a one-dimensional barcode, and a two-dimensional barcode.

8. The identification method of an integrated circuit chip as claimed in claim 2, wherein the identification information set comprises least one of a character code, a one-dimensional barcode, and a two-dimensional barcode.

9. The identification method of an integrated circuit chip as claimed in claim 3, wherein the identification information set comprises least one of a character code, a one-dimensional barcode, and a two-dimensional barcode.

10. The identification method of an integrated circuit chip as claimed in claim 4, wherein the identification information set comprises least one of a character code, a one-dimensional barcode, and a two-dimensional barcode.

11. The identification method of an integrated circuit chip as claimed in claim 1, wherein the identification step comprises identifying the surface structure of the integrated circuit chip by an identification device, and generating the structural information set by the surface structure, wherein the identification device is an optical identification device.

12. The identification method of an integrated circuit chip as claimed in claim 2, wherein the identification step comprises identifying the surface structure of the integrated circuit chip by an identification device, and generating the structural information set by the surface structure, wherein the identification device is an optical identification device.

13. The identification method of an integrated circuit chip as claimed in claim 3, wherein the identification step comprises identifying the surface structure of the integrated circuit chip by an identification device, and generating the structural information set by the surface structure, wherein the identification device is an optical identification device.

14. The identification method of an integrated circuit chip as claimed in claim 1, wherein the optical identification device is one of a visible light identification device comprising a visible light sensor, a laser identification device comprising a laser sensor, and an X-ray identification device comprising X-ray sensor.

15. The identification method of an integrated circuit chip as claimed in claim 1, wherein the identification step comprises identifying a surface structure or an internal structure of the integrated circuit chip by an identification device, and generating the structural information set according to the surface structure or the internal structure, wherein the identification device is an ultrasonic identification device.

16. An identification system of an integrated circuit chip, comprising:
an identification module, configured to identify a surface structure or an internal structure of the integrated circuit chip, and to generate a structural information set according to the surface structure or the internal structure; and
an identification information generation module, connected to the identification module, and configured to convert the structural information set to an identification information set of the integrated circuit chip.

17. The identification system of an integrated circuit chip as claimed in claim 16, wherein the identification system of an integrated circuit chip further comprises an identification information output module connected to the identification information generation module, and configured to output the identification information set into a digital file, or to simultaneously output the structural information set and the identification information set into digital files respectively.
